(19) United States
(12) Patent Application Publication
(10) Pub. No.: US 2012/0261476 A1
(43) Pub. Date: Oct. 18, 2012

(54) WIRELESSLY DETECTABLE TAMPER EVIDENT SEAL

(75) Inventors: Gary Bortz, St. Ives (AU); Jonathan Hugh Elcombe, Frenchs Forest (AU); Kevin John Partridge, Frenchs Forest (AU)

(73) Assignee: Visibility Solutions Pty Ltd, Frenchs Forest (AU)

(21) Appl. No.: 13/386,853

(22) PCT Filed: Jul. 26, 2010
(86) PCT No.: PCT/AU10/00936

§ 371 Date: Jul. 2, 2012

(30) Foreign Application Priority Data
Jul. 24, 2009 (AU) 2009903461

(51) Int. Cl. G06K 19/077; B65B 51/00; H05K 7/00

(52) U.S. Cl. 235/492; 361/679.01; 361/807; 53/416

(57) ABSTRACT

A wirelessly detectable tamper-evident seal (1) including a receptacle part (10) and a frangible part (50), the receptacle part (10) including a first receptacle (10a) and a second receptacle (10b-d) attachable to a container to seal a closure of the container and the frangible part (50) including a first portion (51) and a second portion (52) frangibly connected to each other, the first receptacle (10a) adapted to receive the first portion (51) and the second receptacle (10b-d) adapted to receive the second portion (52), the frangible part (50) including a transponder (54), the second portion (52) able to be trapped against movement in the reverse direction in the second receptacle (10b-d) to effect a tamper evident seal between the first and second receptacles (10a-d), wherein the transponder (54) includes at least two circuit interruption locations (94a, 94b) that must be connected to activate the transponder (54) and the transponder (54) is activatable by inserting the second portion (51) in the second receptacle (10b-d) whereby to connect both or all circuit interruption (94a,94b) locations.

### FIELD OF INVENTION

This invention relates to a tamper evident seal. More particularly, this invention relates to a wirelessly detectable tamper evident security seal.

### BACKGROUND ART

The following references to and descriptions of prior proposals or products are not intended to be and are not to be construed as, statements or admissions of common general knowledge in the art. In particular, the following prior art discussion does not relate to what is commonly or well known by the person skilled in the art, but assists in the understanding of the inventive step of the present invention of which the identification of pertinent prior art proposals is but one part.

Tamper evident security seals comprising wireless transponders, particularly radio frequency identification (RFID) transponders have been described. However, such earlier attempts typically allow a transponder to retain at least some activity after a seal has been broken. Prior art attempts also generally result in the destruction of the majority of component parts so that they cannot be re-used.

An object of the present invention is to ameliorate the aforementioned disadvantages of the prior art or to at least provide a useful alternative thereto.

### STATEMENT OF INVENTION

Accordingly, in one aspect of the invention, there is provided:

a wirelessly detectable tamper-evident seal including a receptacle part and a frangible part, the receptacle part including first and second receptacles attachable to a container respectively either side of a closable opening of the container and the frangible part including first and second portions frangibly connected to each other,
the first receptacle adapted to receive the first portion and the second receptacle adapted to receive the second portion, the frangible part including a transponder, the second portion able to be trapped against movement in the reverse direction in the second receptacle to effect a tamper evident seal between the first and second receptacles, wherein the transponder includes at least two circuit interruption locations that can be connected to activate the transponder and the transponder is activatable by inserting the second portion in the second receptacle whereby to connect both or all circuit interruption locations.

The breaking of the seal is preferably accompanied by the combination of the weakening or the breaking of the frangible connection between the first and second portions. Preferably, the separation of the wireless detectable portion from the frangible part disconnects and renders inoperable the transponder. The receptacle part is preferably undamaged and reusable with a replacement frangible part.

The transponder may be a radio transceiver. The transponder may automatically transmit an outgoing signal upon reception of a designated incoming signal from an associated device. The incoming and outgoing signals may be transmitted wirelessly. The transponder may include a wirelessly detectable portion that does not require a direct wire connection to an associated transmitting/receiving device, but receives wirelessly transmitted signals in operation.

The transponder may be any one of a range of transponder types of which the skilled person will be familiar. The preferred transponder is an RF transponder capable of being read by an RF transponder reader when the transponder is connected to an antenna which makes the transponder operable and able to be interrogated. The transponder may be passive, relying on electromagnetic radiation generated by an RF reader to pomp the RF chip through collection of the RF reader signal via the antenna. Alternatively, the transponder, may be actively powered, for example by a solar collector or battery, the battery source of power being most utilitarian out of these active powering options.

The seal is preferably a wirelessly detectable tamper-evident seal. The seal may be adapted to seal a variety of different containers such as safety deposit boxes, money bags and secure paper document containers.

The first portion may be in the form of a head having at least a section that extends outside the footprint of the second portion. The second portion may be in the form of a leg or arm extending from the first portion. The first receptacle may be a chamber adapted to receive the first portion head and the second receptacle may be a chamber or frame adapted to receive the second portion comprising the leg.

The receptacle part may define one or more chambers or may merely include complementary detents adapted to engage corresponding features on the leg. Accordingly, the receptacle part may or may not partially or substantially enclose the head or leg. The receptacle part may be in at least two parts, including a part to stationarily receive the leg and a part to damage the leg or to otherwise disconnect a component of the transponder so to deactivate same. The receptacle part may include a movable part that tilts, pivots or breaks away from the remainder of the receptacle part to deactivate the transponder. The receptacle part may include a main chamber, enclosure or open frame that is adapted to hold the head.

The first and second receptacles may be attachable to a container to seal a closure of the container by means of fasteners, welding, stitching, rivets or any other suitable joining means provided that separation of the receptacle part or a component thereof from the container is visible and not easily restored without visible signs. Preferably, the receptacle parts are attached to the container by fasteners, such as rivets. The container may be made of rigid materials such as metal, wood or plastic and the fasteners may extend through walls in the container and be optionally mounted on or through brackets on the opposed side of the wall.

The frangible part includes first and second portions frangibly connected to each other. The frangible connection may include weakened or score lines. The transponder chip may constitute the portion of the frangible part that is adapted to break away from the remainder of the frangible part structure. Preferably, the frangible part has one or more extensions, arms, legs or other components that are adapted to partially or fully separate to deactivate the transponder. The second portion may be adapted to separate from the first portion on the breaking of the seal.

The second portion is insertable or otherwise engageable to the second receptacle by movement in a first direction. The second portion may then be trapped against movement in the reverse direction in the second receptacle to effect a tamper evident seal between the first and second receptacles.

The transponder may include at least two circuit interruption locations that may be connected to activate the transponder. The transponder may be adapted to operate with one or both circuit interruption locations connected. In practice, over time and re-use, the receptacle parts may wear and engagement connections with the frangible part may develop greater play. Accordingly, it can be an advantage to have at least dual connections for the at least two circuit interruption locations. The transponder may comprise a chip from which extends a pair of unconnected terminals. The transponder may be activatable by inserting the second portion in the second receptacle to connect both or all circuit interruption locations by connecting the pair of unconnected terminals. The chip may be discretely displaceable from the frangible part to disconnect the transponder. This enables the transponder or chip to be virtually completely isolated from any antennae or antenna-like structure that might be effective to continue energizing the chip despite the breaking of the seal. Otherwise, the terminals or the chip itself might enable activation of the passive transponder even though the circuit interruption locations are disconnected.

According to another aspect of the invention, there is provided:

a wirelessly detectable tamper-evident seal including a reusable receptacle part and a single use frangible part, the receptacle part including first and second receptacles attachable to a container to seal a closure and the frangible part including first and second portions frangibly connected to each other,
the first receptacle adapted to receive the first portion, the frangible part including a transponder having a wireless detectable portion; the transponder activatable by cooperation with the second portion which is trapped against movement in the reverse direction in the second receptacle to effect a tamper evident seal between the first and second receptacles,
wherein the breaking of the seal of the receptacle part is accompanied by the combination of the weakening or the breaking of the frangible connection between the first and second portions and the separation of the wireless detectable portion from the frangible part and wherein the receptacle part is undamaged and reusable with a replacement frangible part.

In another aspect, the invention provides:

a method for scaling a container with a wirelessly detectable tamper evident seal having a receptacle part comprising first and second receptacles and a frangible part comprising first and second portions frangibly connected to each other and including a transponder having a wireless detectable portion, the second portion including an electrical connector adapted to activate the transponder, the method comprising the steps of:
attaching the first receptacle and the second receptacle to the container whereby joining the first and second receptacles is associated with closure of the container;
receiving the first portion in the first receptacle;
inserting the second portion by movement in a first direction whereby to trap the second portion in the second receptacle against movement in the reverse direction;
activating the transponder by contact with the electrical connector;
scaling the receptacle part together to tamper-evidently seal the container;
weakening or breaking the frangible connection between the first and second portions to break the seal;
separating the wireless detectable portion from the frangible part to make the transponder inoperable; and
permitting the second portion to removed from the second receptacle so that the receptacle part is ready for re-use.

The frangible part may have the transponder attached in a number of ways. For example, the transponder antenna may be attached to the frangible part by winding, etching, stamping or printing.

A further step in the method may include:

inserting a transponder including an antenna between the frangible part and a cover correspondingly shaped therefor, in parallel plane relationship, and joining the frangible part and the cover together.

The joining process may be alternatively, achieved by adhesive or heat fusion.

Optionally the joining process may be achieved by welding. The welding process may include ultrasonic welding, spot welding, heat welding.

The cover may include a breakable section positionally corresponding to the wireless detectable portion, such as an RF chip.

### BRIEF DESCRIPTION OF THE DRAWINGS

The invention may be better understood from the following non-limiting description of preferred embodiments, in which:

FIG. 1a is an exploded view or a tamper evident seal according to a first embodiment of the invention;

FIG. 1b is a top plan view of the frangible part and cover inserted in the receptacle part according to the first embodiment shown in FIG. 1a;

FIG. 1c is a front elevation of the first embodiment shown in FIG. 1b;

FIG. 1d is a side elevation of the first embodiment shown in FIG. 1b;

FIG. 2a is a rear perspective view of the frangible part and terminal connector according to the first embodiment;

FIG. 2b is a rear elevation of the frangible part showing a terminal in place shown in FIG. 2a;

FIG. 2c is a side section of the portion of the frangible part through section A-A shown in FIG. 2b;

FIG. 3a is a front elevation of the frangible part and cover according to another embodiment;

FIG. 3b is a side elevation of the frangible part shown in FIG. 3a;

FIG. 3c is a rear elevation of the frangible part and cover shown in FIG. 3a;

FIG. 3d is an end elevation of the leg portion only of the frangible part and cover shown in FIG. 3a;

FIG. 3e is a front elevation of the cover shown in FIG. 3a;

FIG. 3f is a rear elevation of the cover shown in FIG. 3a;

FIG. 3g is a rear perspective view of the frangible part and terminal connector according to the embodiment shown in FIG. 3a;

FIG. 3h is a rear elevation of the frangible part showing a terminal in place as shown in FIG. 3g;

FIG. 3i is a side elevation of the frangible part and cover combination through section A-A of FIG. 3h;

FIG. 4 is a schematic representation of a transponder according to one aspect of the invention;

FIG. 5a is an exploded view of a tamper evident seal according to another embodiment of the invention;

FIG. 5b is a top plan view of the frangible part and cover inserted in the receptacle part according to the embodiment shown in FIG. 5a;

FIG. 5c is a front elevation of the first embodiment shown in FIG. 5b;

FIG. 5d is a side elevation of the first embodiment shown in FIG. 5b;

FIGS. 6a-6b are schematic perspective views of a frangible part having an RF chip and antenna according to another embodiment;

FIG. 7a is a schematic perspective view of a mid-tear seal and barcode arrangement according to another embodiment;

FIGS. 7b-7e are schematic perspective views of the frangible part or components thereof according to the embodiment shown in FIG. 7a;

FIG. 8a is a schematic front elevation of a T-shaped tag according to a preferred embodiment;

FIG. 8b is a schematic perspective view of a frangible part with a mid-leg terminal according to another embodiment;

FIGS. 9a 9b are schematic perspective views of the frangible part or components thereof according to a double leg seal embodiment;

FIGS. 10a 10b are schematic perspective view of frangible parts having side barbs;

FIG. 10c is a schematic perspective view of a second receptacle with complementary downward side barbs to cooperate with either embodiment shown in FIGS. 10a-10b;

FIG. 10d is a schematic perspective view of a second receptacle component in the form of a sprung pivot pin;

FIG. 10e is a schematic perspective view of a second receptacle capable of pivoting about an axis normal to the plane of the frangible part;

FIG. 10f is an exploded schematic perspective view of a frangible part leg and second receptacle with complementary downwardly extending barbs;

FIG. 11a-11c are schematic perspective views of a seal and components thereof having a flip out chamber or second receptacle according to another embodiment;

FIG. 12a is a schematic perspective view of a seal having a tilt out chamber according to another embodiment; and

FIG. 12b is an exploded schematic perspective view of the seal according to the embodiment shown in FIG. 12a.

### DETAILED DESCRIPTION OF TILE DRAWINGS

Preferred features of the present invention will now be described with particular reference to the accompanying drawings. However, it is to be understood that the features illustrated in and described with reference to the drawings are not to be construed as limiting on the scope of the invention.

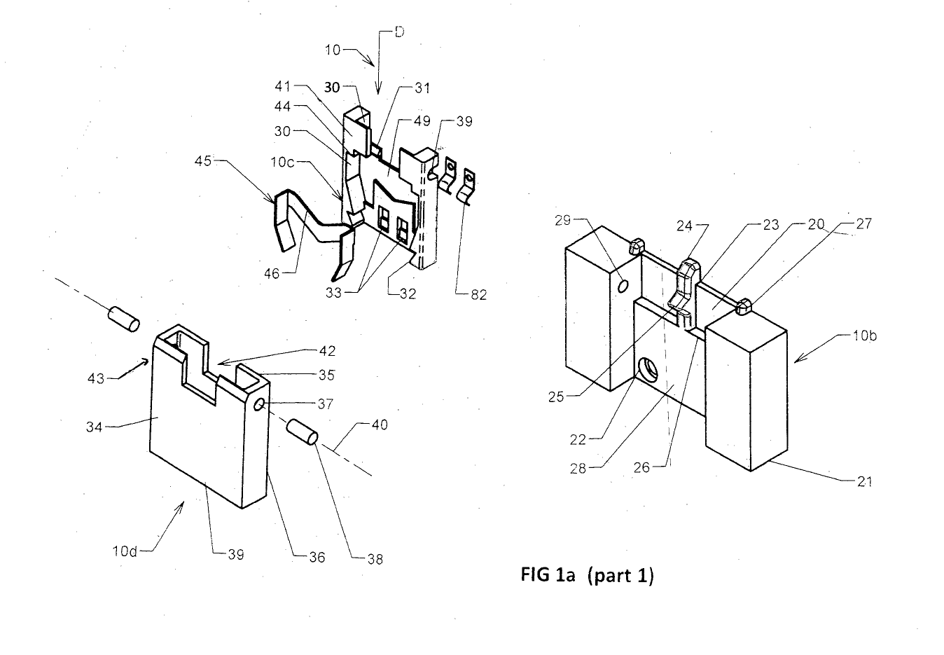

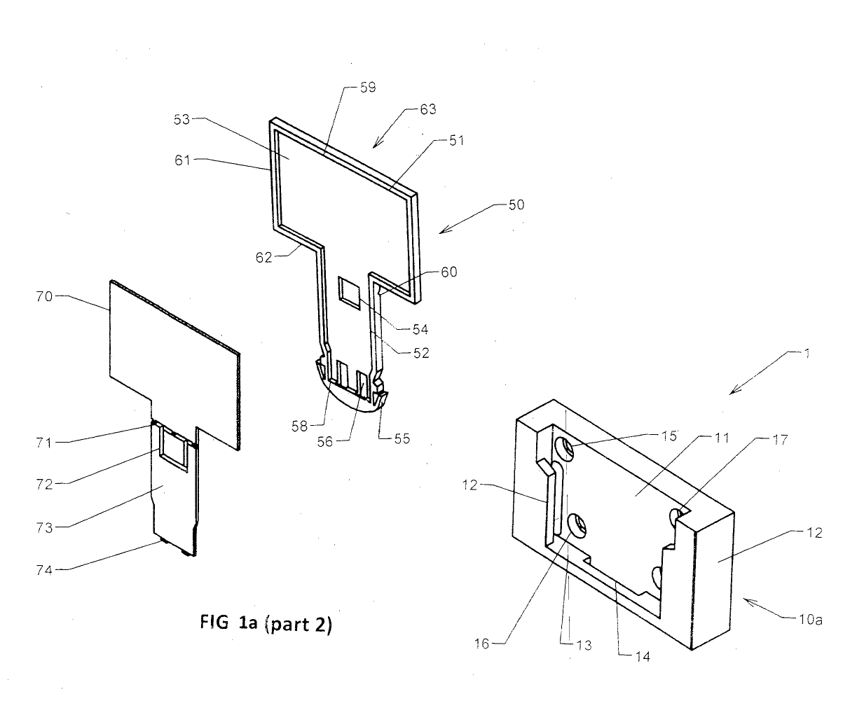

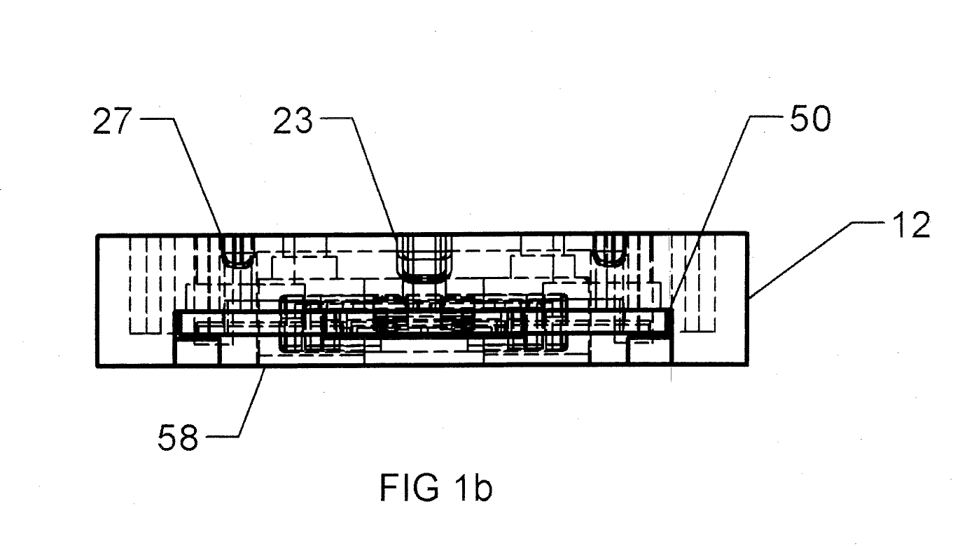

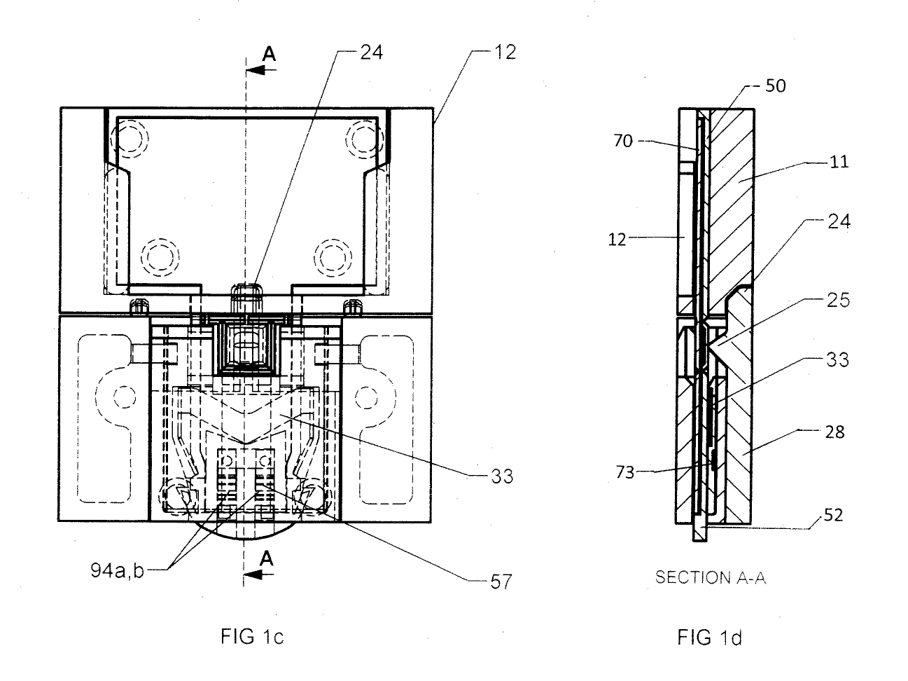

In FIGS. 1a-1d there is shown an exploded view of a tamper evident seal combination 1 comprising a receptacle part 10 and a frangible part 50.

The frangible part 50 comprises a first portion in the form of a broad head 51 and a second portion in the form of a leg 52.

The frangible part includes an RFID attached to its inner surface 53 as described in more detail below. The RFID includes an RF chip 54 frangibly housed in the leg 52 whereby the frangible part 50 comprises an RF antennae extending broadly across the surface 53 and operatively connected to the RF chip 54. However, the RF chip 54 is mounted on a rectangular panel frangibly connected to the surrounding leg 52. The lower portion of the leg 52 comprises a pair of side barbs 55 adapted to ensure irreversible reception into the receptacle part 10 as described below. The side barbs 55 comprise short, deflectable arms that allow entry into the receptacle part 10 over complimentary ramps 31 whereby to lock the barbs in place once they have travelled past the ramps. The lower portion of the leg 52 further includes a pair of slotted apertures 56 through which extend a corresponding pair of terminals 57 that form part of the receptacle part 10. The lower portion of the leg 52 further includes a pair of frontward extending barbs 58 that may be formed from leg material that is punched out to form the aperture slots 56.

The internal surface 53 of the frangible part 50 is covered by a cover 70 that protects the RFID. The internal surface 53 is recessed relative to a raised peripheral edge 59 to so enable the cover 70 to lie flush within the peripheral edge 59 for insertion into the receptacle part 10.

The frangible part 50 includes a weakened portion 60 extending close to the intersection between the broad head 51 and the leg 52. Preferably, the weakened portion 60 is as close as possible to the top line of the frangible edge of the rectangular panel bearing the RF chip 54. A corresponding weakened line 71 is provided on the cover 70. Furthermore, a frangibly mounted panel 72 adapted to align in registration with the RF chip 54 is provided in the corresponding leg portion 73 of the cover 70. Preferably, the weakened portion 71 forms a top edge of the cover panel 72. The cover leg 73 includes a pair of spaced shallow tabs 74 adapted to rest at the base of the front extending tabs 58.

The receptacle part 10 comprises four main parts, a first receptacle or other housing 10a, and a lower second receptacle comprising a second housing 10b, leg receiving receptacle 10c and pivotal sleeve 10d.

The other housing or first receptacle 10a comprises a solid body having a rear wall 11 and two spaced side pillars 12 at either end of the rear wall 11. A pair of downwardly slotted recesses 17 are defined by the side pillars 12 and the rear wall 11 to provide an open cavity or track into which the side edges 61 of the broad head 51 may slide and engage. The upper first housing 10a further includes a lower wall 13 extending normal to the rear wall 11 and pillars 12 on top of which the lower edge 62 of the peripheral edge 59 may rest when the frangible part 50 is fully engaged with the receptacle part 10. The floor 13, together with the rear wall 11, further defines an elongate slot 14 adapted to receive the leg 52. The rear wall 11 further includes apertures 15 to receive fasteners, so that the upper housing 10a may be mounted to, for example, a lid 78a or other closure of a container 77 to be secured. The rear wall further includes a pair of spaced side slot apertures 16 in the rear wall 11 adjacent the recesses 17.

The lower second housing 10b comprises a stepped rear wall 20 that terminates at each side end with a pair of solid posts 21. The lower rear wall 20 includes a pair of apertures 22 (one aperture is obscured by right hand post 21) to receive fasteners to mount the lower housing 10b to a container wall 79 adjacent the opening 77a closed by the closure. Centrally disposed on the rear wall 20 is a ridge member 23 comprising an upwardly extending locating protrusion 24 and a frontwardly extending protrusion 25. These protrusions 24, 25 are continuous with each other and with a horizontal step 26 forming part of the rear wall 20 as alluded to above. Also extending above the line of the rear wall 20 and the side posts 21 are a pair of upwardly extending locator lugs 27 that, together with the upwardly extending protrusion 24, are adapted to register with corresponding apertures in the floor 13 of the upper housing 10a to ensure correct vertical alignment between the upper and lower housings 10a, b and no rotation about a vertical axis of the upper first housing relative to the lower housing 10b.

The shoulder 26 provides a thickened lower rear wall section 28 which, together with the posts 21, defines a recess in which the pivotable sleeve 10d may be suspended. As will be described below, the outwardly extending protrusion 25 operates as a stationary punch adapted and positioned to forcibly push against the RF chip panel 54 and, as a consequence, the corresponding frangible panel 72.

The skilled person will appreciate that, although the frangible part 50 is shown as a T-shaped member, it may also be L-shaped or otherwise shaped whereby the head 51 presents a broader lower surface than the footprint of the leg 52, so that the second receptacle 10b-c into which the leg 52 extends does not slidably receive the head 51. The head 51 has at least one lateral arm or extension 76 outside the lateral line 69 of the peripheral edge 59 in the region of the leg 52. Moreover, the centrally disposed ridge member 23 comprising the protrusions 24, 25 may, instead, be laterally disposed to complement a similarly laterally disposed frangible RF chip panel and still achieve equivalent functionality to the embodiment shown in FIG. 1a. In like manner, the upwardly extending lugs 27 may be variously positioned in alignment with correspondingly positioned apertures in the floor 13.

The leg receptacle 10c is an insert adapted to be slidably received within the pivotal sleeve 10d. The internal side walls 30 of the leg receptacle 10c provide a pair of inwardly and downwardly sloping ramps 31 over which the side barbs 55 of the leg 52 are adapted to ride as the leg 52 is pressed downwardly into the leg receptacle 10c until the side barbs 55 are caught behind an angular shoulder 32 in the side walls 30 of the leg receptacle 10c and locked against reverse movement in a direction opposite to direction D so that the leg 52 is trapped in the leg receptacle 10c. The separate formation of the leg receptacle 10c and the pivotal sleeve 10d enables easier assembly of the internal components of the insert 10c and pivotal sleeve 10d. However, it will be appreciated that the combination of receptacle parts 10c, 10d could be integrally formed as a single pivotal chamber. A lock 45 is housed in the chamber defined by the leg receptacle 10c and the pivotal sleeve 10d.

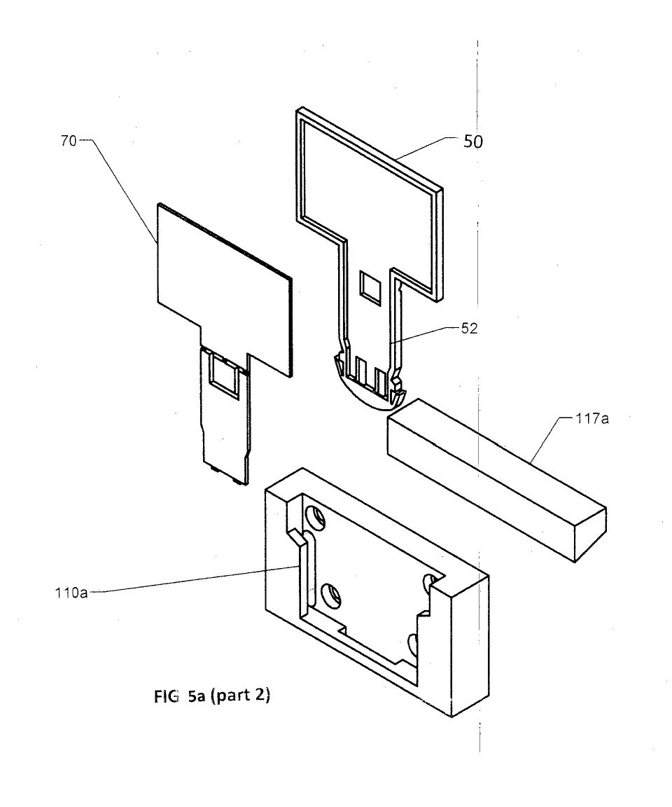

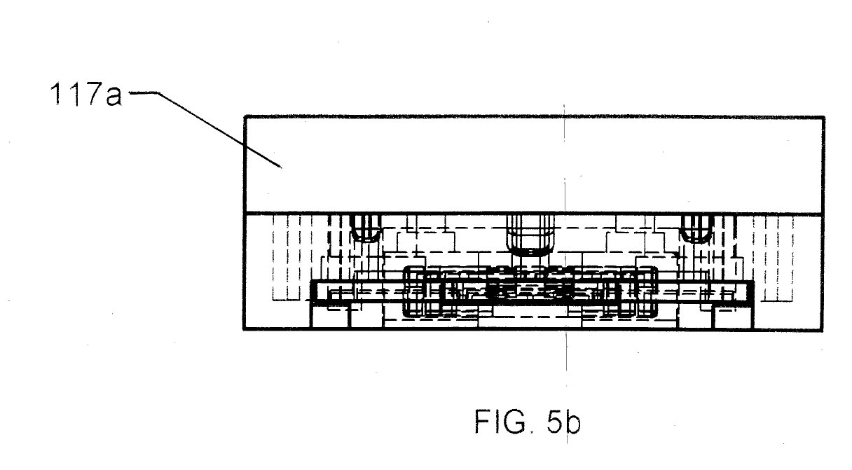

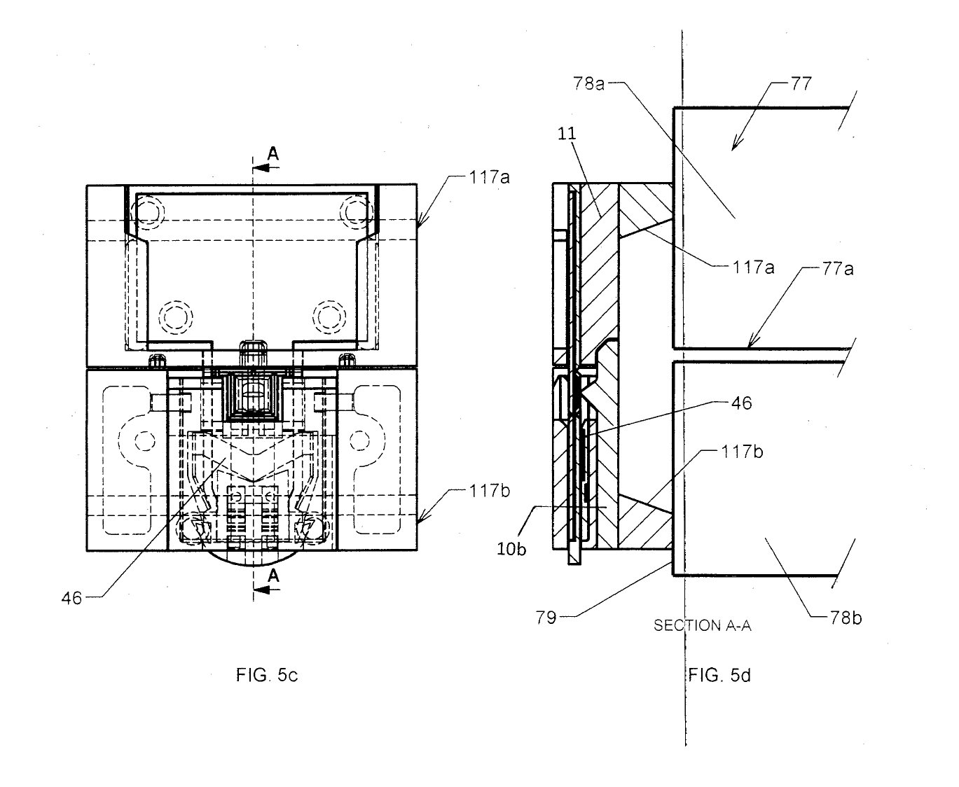

As most clearly shown in the embodiment shown in FIGS. 5a-d the lock 45 is a generally “M” or channel-Shaped member comprising a V-shaped bridge member 46 and a pair of spaced side legs 47a,b depending from either end of the V-shaped bridge 46. The lock 45 is shaped to follow the internal shape of the leg receptacle 10c so that it may be inserted and wedged in the leg receptacle and pivotal sleeve 10d combination without requiring additional securement. The V-shaped bridge 46 lies in a first plane flat against the internal surface of the rear wall 49 or the insert 10c. The side legs 47a,b each depend from the V-shaped bridge 46 and lie substantially in planes normal to the first plane and terminate at free ends 48a,b that follow the contours of the internal side walls 30 and the ramps 31. The lock 45 is preferably made using an abrasion-resistant material such as metal or plastic, including materials such as spring steel, aluminium or acctal. The free ends 48a,b provide a hard edge against which the barbs 55 are trapped when the seal 1 is in place.

The pivotal sleeve 10d comprises a rectangular or square box with front, rear and side walls 34, 35, 36 that house the leg receptacle 10c and together with the leg receptacle 10c provides a chamber to trap the leg 52.

The upper portions of the pivotal sleeve 10d side walls 36 include a pair of coaxial apertures 37 through which extend a pair of spaced pivot pins 38 that are adapted to extend into corresponding apertures 29 in the internal side walls of the side posts 21. During assembly, the leg receptacle 10c is first inserted with the lock 45 in place into the pivotal sleeve 10d with the pivot pins already engaged with corresponding saddles 39 formed in the side walls 30 of the leg receptacle 10c. Once the leg receptacle 10c is inserted, the sleeve 10d may be brought into registration whereby the pins 38 are pushed, either by automated or manual means, side ways to enter the lower housing apertures 29 to enable the pivotal sleeve 10d to rotate about the pin axis 40 relative to the lower housing 10b.

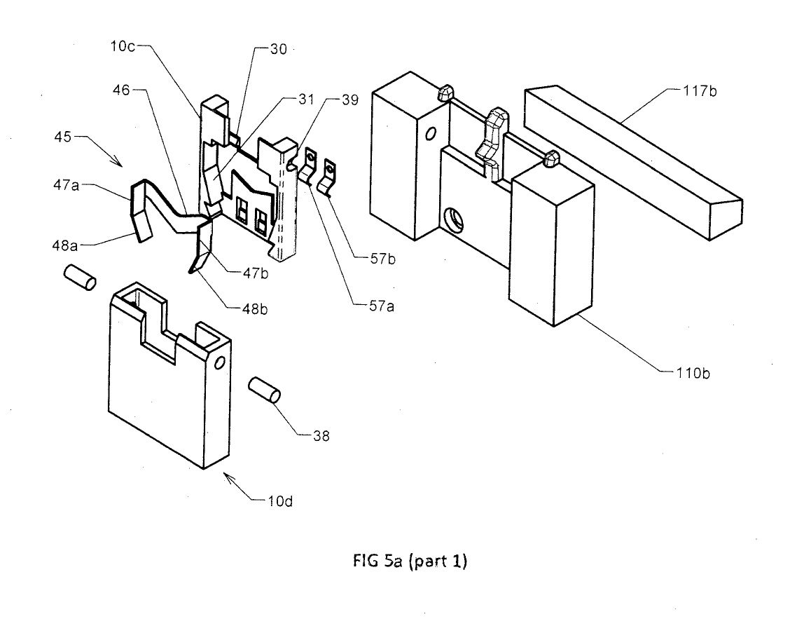

In use, the frangible part 50 and the cover 70, when separate from the receptacle part 10, includes an inactive RF transponder because the absence of the spaced connectors 82 represent a break in the transponder 90 circuit. On insertion of the frangible part 50 into the receptacle part 10, as shown in FIG. 4 the spaced connections 82 come into contact with the RF transponder circuit terminals 92 and the antennae 93a, b terminals whereby to complete the RF transponder 90 circuit thereby rendering the RF transponder 90 circuit active. The seal 1 thereby provides a tamper evident seal which is able to communicate, its active state with a suitable RF reader to detect the active state of the transponder 90 of the seal 1. The seal 1 is broken by lifting the pivotal sleeve 10d and rotating it about the pin axis 40.

The front and rear walls 34, 35 of the pivotal sleeve 10d and a front broken wall 41 of the leg receptacle 10c include cut away portions 42 that permit the RF panel 54 to flex and break away partially or fully from the leg 52 as the pivotal sleeve 10d rotates about the pin axis 40 so that the frontwardly extending protrusion 25 bears on the frangible panel 54 as the top portion 43 of the pivotal sleeve 10d moves towards the protrusion 25. Concurrently, the upper section of the leg 52 is caused to flex as the leg 52, trapped in the leg receptacle 10c, rotates with the pivotal sleeve 10d. The frangible panel 54 and the weakened connection 60 eventually fail so that the leg 52 separates from the remainder of the frangible part 50 (predominantly comprising the broad head 51) and the RF chip panel 54 partially or completely breaks away from the leg 52 and preferably drops through the leg receptacle 10c and pivotal sleeve 10d, typically falling out of the seal 1.

Accordingly, the seal arrangement 1 provides a visible indication that the seal 50 has been broken and, the severing of the RF chip panel 54 from the antennae 93a, b has the effect of deactivating the RF transponder 90, so that it is no longer detectable by an RF reader.

Referring specifically to FIGS. 1b 1d, the arrangement of the seal 1 shown in FIG. 1a as an exploded view is now shown assembled. The upper V-shaped bridge member 46 of the lock 45 is aligned parallel with the internal surface of the rear insert wall 49 thereby allowing the leg 52 to pass by as the leg 52 is inserted into the leg receptacle 10c pressing the connectors 82 into contact with the antennae terminals of the interrupted circuit locations 94a,b. The connectors 82 at rest do not complete the connection between the antennae terminals.

The connectors 82 are mounted in connector apertures 33 near the base of the leg receptacle 10c. Each connector 82 has an upper tab with an aperture or protrusion that is used to locate the connectors 82 on a corresponding protrusion or aperture on the rear surface of the rear insert wall 49 just above each aperture 33. Each connector 82 also has an angled lower end that extends through the aperture 33 and rests on the rear insert wall 49 just below the corresponding aperture 33. The exposed lower end of each connector 82 provides a sufficiently broad surface to provide the connection between each antenna 93a,b and chip terminal 92.

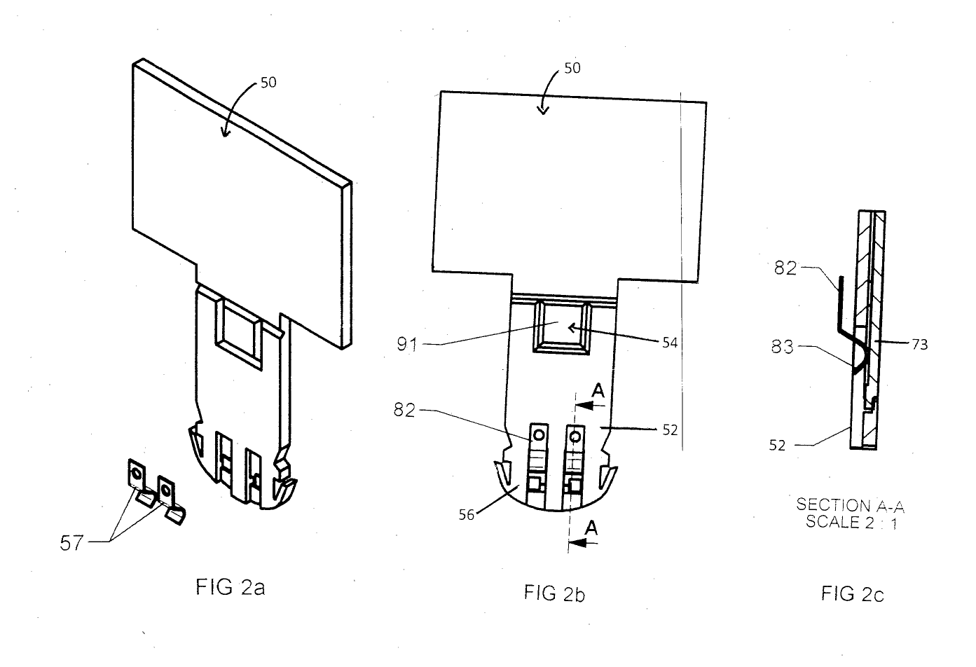

In FIGS. 2a-c the RF chip 91 on panel 54 of leg 52 is electrically connected to spaced connectors 82, being metal S-shaped tags adapted to extend through to the leg apertures 56 and in use extend towards the cover 70 so that the terminal connectors 82 complete the transponder circuit. When seal 1 is assembled, the terminal connectors 82 bear against the terminals 92 and antennae terminal sites 94a,b. Each connector 82 connects the circuit at a different location so that each circuit interruption location 94a,b is separately connected.

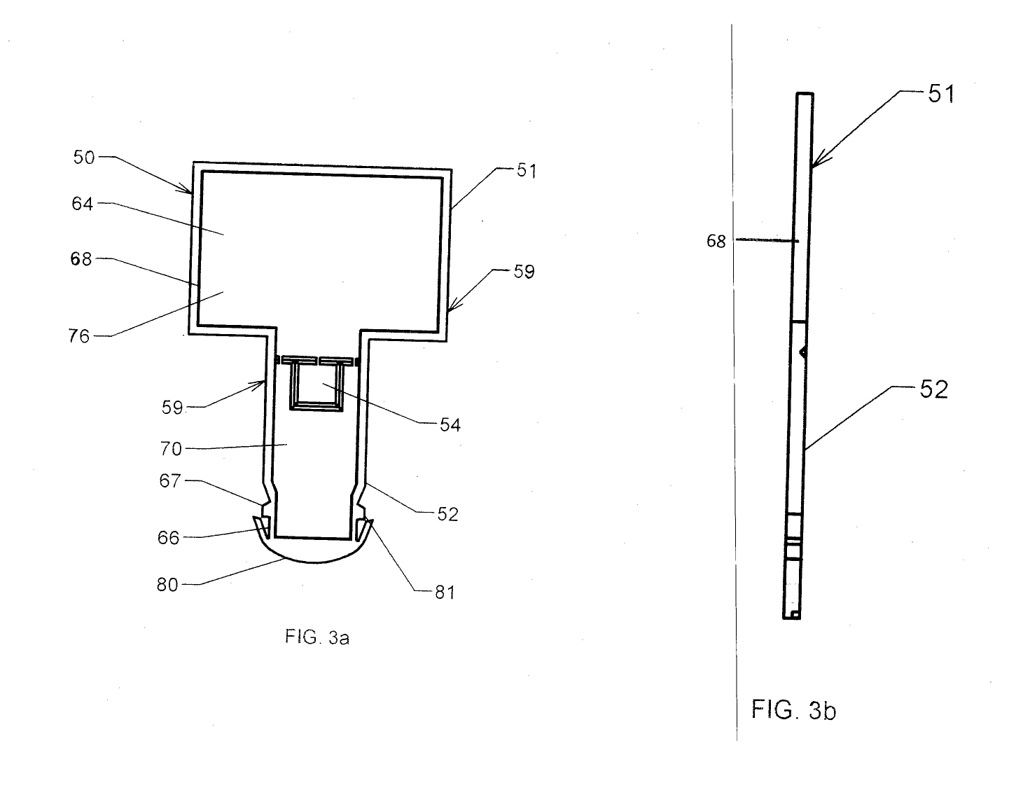

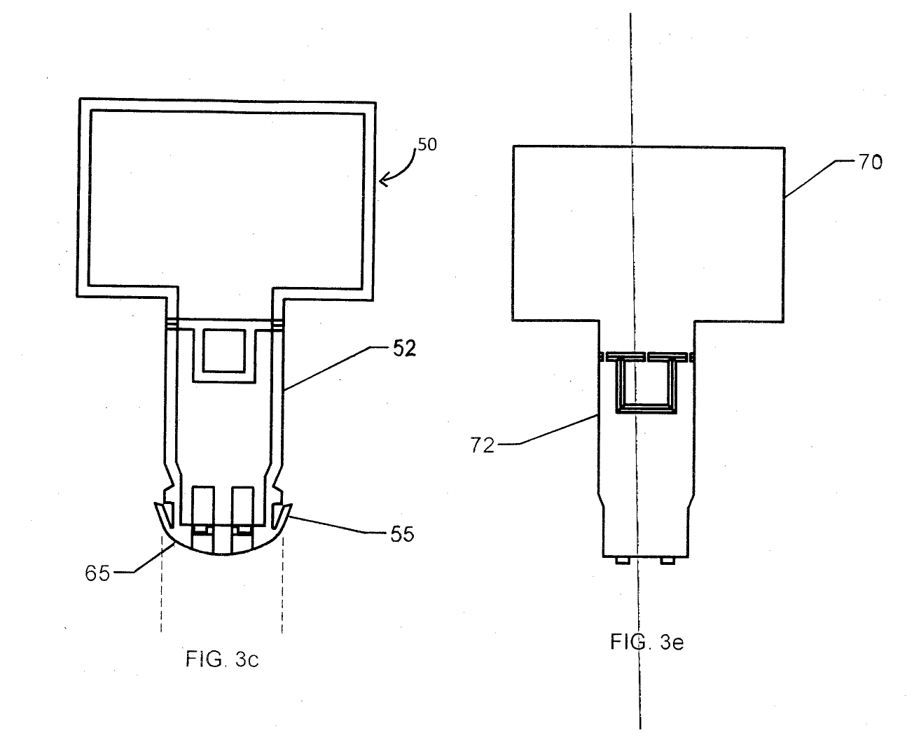

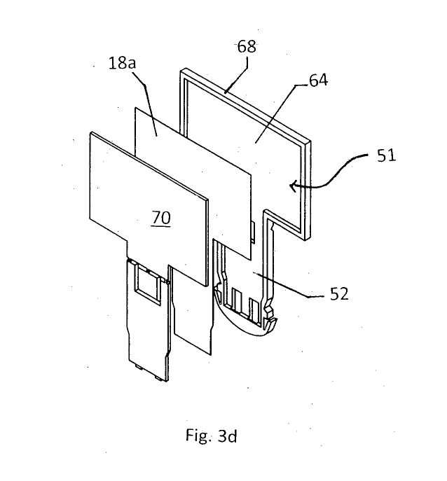

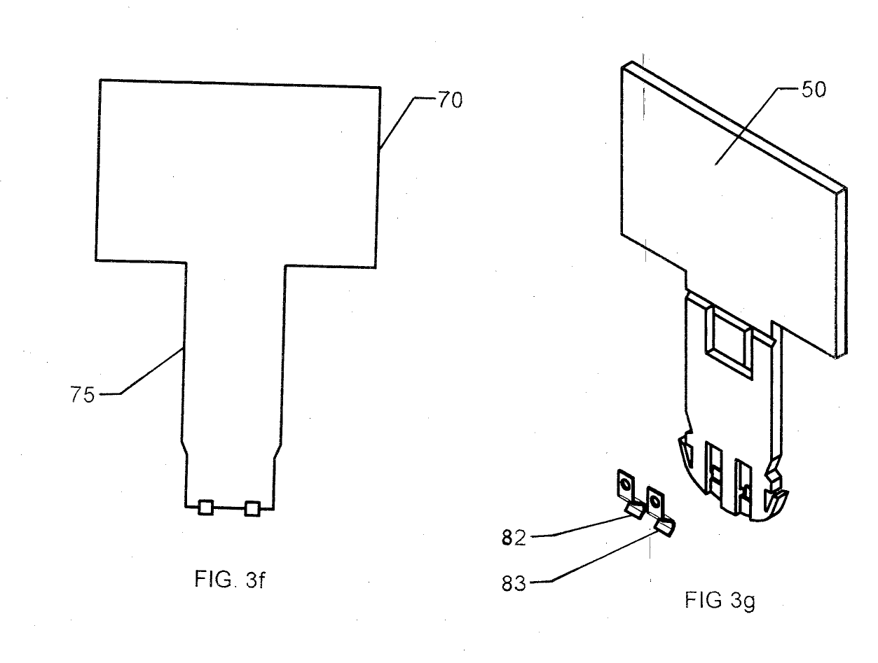

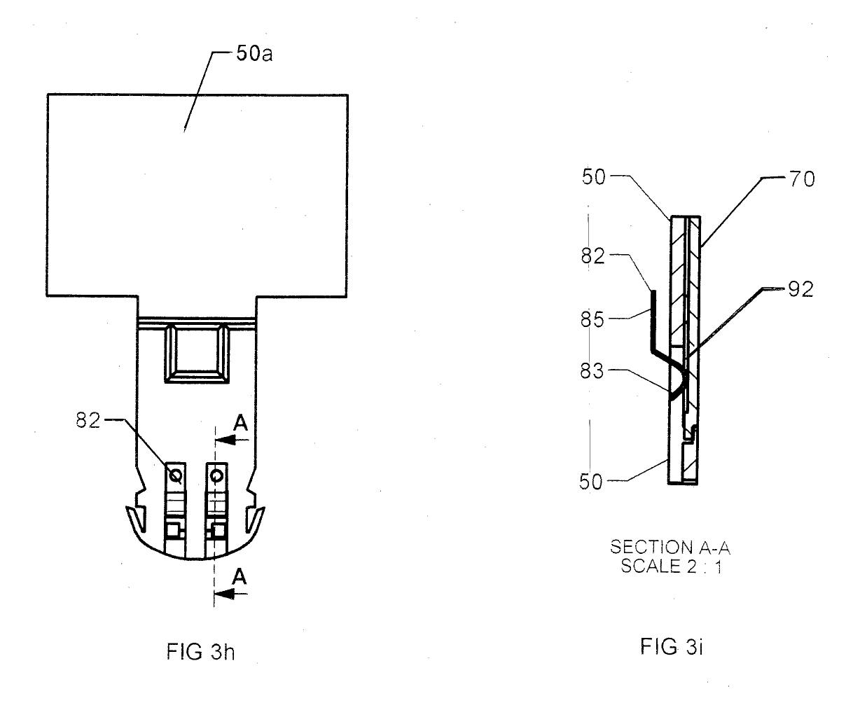

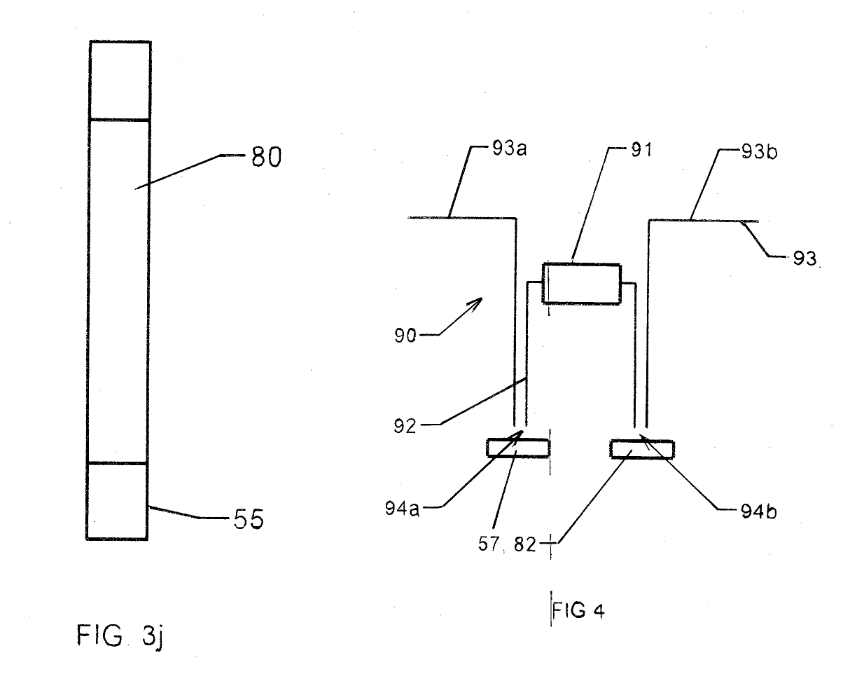

In FIGS. 3a-i, the frangible part 50 and cover 70 are shown combined. The cover 70 includes a shape complementary and corresponding to the shape of the frangible part 50 predominantly as defined by a raised wall 68 of consistent height forming the peripheral edge 59. The raised wall 68 extends proudly from the general plane of the main body plate 64 of the frangible part 50 to define the recess into which the cover 70 is shaped to fit flush with the raised wall 68. As shown in FIG. 2b, the plate 64 is generally planar. However, the broad head 51 may be thicker in proportion to the leg 52. For example, the head may be thicker than the leg 52 but no wider and may even be narrower in front view as long as at least a portion of the head 51 sits outside the footprint of the leg 52 due to a front, rear and/or side projection. Accordingly, the head 51 limits the extent to which the unbroken frangible part 50 can travel into the receptacle part 10 so that only the leg 52 can extend into the second receptacle 10b-c. However, preferably the head 51 is wider than the leg 52. The footprint dimensions of the leg 52 are shown in FIG. 3d, noting that barbs 55 are inwardly deflectable so slightly vary the leg 52 footprint.

The leg 52 is preferably made of a thin and flexible material. Preferably, the leg 52 is adapted to flex or bend outside the plane of the portion of the plate 64 in the head 51.

The weakened connection 60 is preferably aligned with the pin axis 40, so that the leg 52 material is not necessarily flexible and may be substantially rigid. Preferably the front protrusion 25 acts as a punch to displace or remove the chip panel 54 and hence the RF chip 90. The protrusion 25 may be positioned in line with the height of the pin axis 40. In any case, the chip panel 54 may be positioned marginally higher than the protrusion 25. If the pivotable sleeve 10d is lifted, the distance between the pin axis 40 and the base 42 of the sleeve 10e is much longer than the distance between the chip panel 54 and the pin axis 40. Considerable leverage is available to force the chip panel 54 against the punch or protrusion 25 as chip panel 54 is rotated about the pin axis 40 downwardly onto the pima 25 and to apply force to the weakened connection 60.

Preferably, the chip panel 54 is aligned centrally in the horizontal position and as close to the weakened connection 60 as possible. However, the chip panel 54 may alternatively be positioned off-centre relative to the leg 52 and may be aligned, for example with the side edge 61. The chip panel 54 may extend the full width of the leg 52 so that the lower portion of the leg 52 below the lowest edge of the chip panel 54 may be adapted to break off or fracture.

The barbs 55 extend upwardly from the base 65 of the leg 52. Immediately inwardly adjacent the barbs 55 are recesses 66 defining space into which the barbs 55 are adapted to flex as they deflect inwardly to enable passage of the lower portion of the leg 52 as it passes between the front panel 41 and the internal side walls 30 of the leg receptacle 10c. Immediately above each of the barbs 55 is a small spur 67 that extends from the peripheral edge 59 and forms part of the raised wall 68. The barbs 55 at rest lie outside the lateral line 69 of the peripheral edge 59 in the region of the leg 52 and of the spurs 67. As the leg 52 is inserted into the leg receptacle 10c, the convexly curved leading lower edge 80 of the leg 52 performs a self-centering function to evenly align the outwardly extending barbs 55 against the opposed internal side walls 30 of the insert 10c. The upper portion of the internal side walls 30 of the insert 10c may include opposed ramparts 43 that extend inwardly relative to the remainder of the internal side walls 30 and are spaced to correspond to the side edge lateral line 69. The barbs 55 deflect inwardly as they travel passed the ramparts 43, but may be withdrawn in the reverse direction as the ramparts 43 do not include a lower abrupt shoulder but a smooth ramp surface on their downward side. However, once the barbs 55 pass the ramps 31, the leg 52 cannot be withdrawn by reversing the direction of travel. Once the leg 52 is locked into the insert 10c, the spurs 67 rest in the wall recesses 44 defined by the internal side walls 30 and the barbs 55 resiliently extend outwardly in the angular recess defined by the ramps 31.

In FIGS. 3e and 3f there is shown the front and rear profiles of the cover 70 which follow the internal contours and shape defined by the raised wall 68. Stamped or moulded into the front face of the cover 70 is the corresponding frangible panel 72. Although the frangible panel 72 could effectively be scored or otherwise formed on the rear face of the cover 70, it is preferred to present a smooth and featureless surface 75 facing the frangible part 50 and the antenna 93 of the transponder 90. The antenna 93 may be fragile and potential for damage is preferably minimised during the installation or the seal 1 by the protection afforded by the cover 70.

In FIGS. 3g-3i, the terminal connectors 82 extend into the pair of slots 56 in the lower portion of the leg 52. The terminal connectors 82 include 83 that are configured to project a relative broad connecting surface into the slots 56. Each terminal connector 82 is effective to electrically complete the otherwise incomplete circuit of the antennae 93 and the transponder 90 at the circuit interruption locations 94a, b on the leg 52.

In FIG. 3i, a side profile of the lower leg 52 is shown wherein the terminal connector 82 projects from the leg receptacle insert 10c. The terminal connectors 82 are preferably sprung. For example, it may be formed from low grade sprung steel, so that it actively bears against the terminals of the antennae 93 and the RF chip terminals 92. It will be appreciated by the skilled person that, in the preferred embodiments, without the terminal connectors 82 hearing on the antennae and chip terminals 94a,b, the spaced terminals 82 will not complete the transponder 90 circuit.

In FIG. 4 the detail of the circuit of the transponder 90 is schematically shown. The transponder 90 includes an integrated circuit chip 91, IC connector terminals 92 and one or more antennae 93. The spaced terminals 82 act as shorting links that complete the transponder 90 circuit when they contact the IC connector terminals 92.

Unlike prior art attempts, the transponder includes at least two circuit interruption locations 94a,b representing the gaps between the antennae 93 and chip terminals 92 rather than a single location. However, the transponder is operable only with the completion or connection of one or both disconnection locations 94a,b. The transponder may comprise a pair of lengths of antennae 93a,b, neither of which are connected to the transponder without the shorting action of the spaced connectors 82. If one antennae 93a,b were to be connected, this might be enough to permit external energy to be supplied by a transponder reader to power the transponder 90 and particularly RF chip 91 and render it active. However, without connection to any length of antenna 93, the transponder 90 is unreadable and therefore in an effectively “off” state. Indeed, in the preferred embodiment, the RF chip 91 is punched out of the leg 52 and circuit so that no length of wire that might act as an antennae is connected to the RF chip 91.

In FIGS. 5a-5d, another embodiment is shown that is similar to that of the first embodiment shown in FIG. 1 with regard to the configuration of the lower leg portion 52. The receptacle parts 110a and 110b are mounted on flange adaptors 117a,b that connect to the container 77 to be sealed. The flanges 117a, b are mounted non-removably to the container walls 79 by permanent fasteners, such as rivets. An upper flange adaptor 117a is fixed to the container lid 78a and a lower flange adaptor 117b is fixed to the base 78b of the container 77.

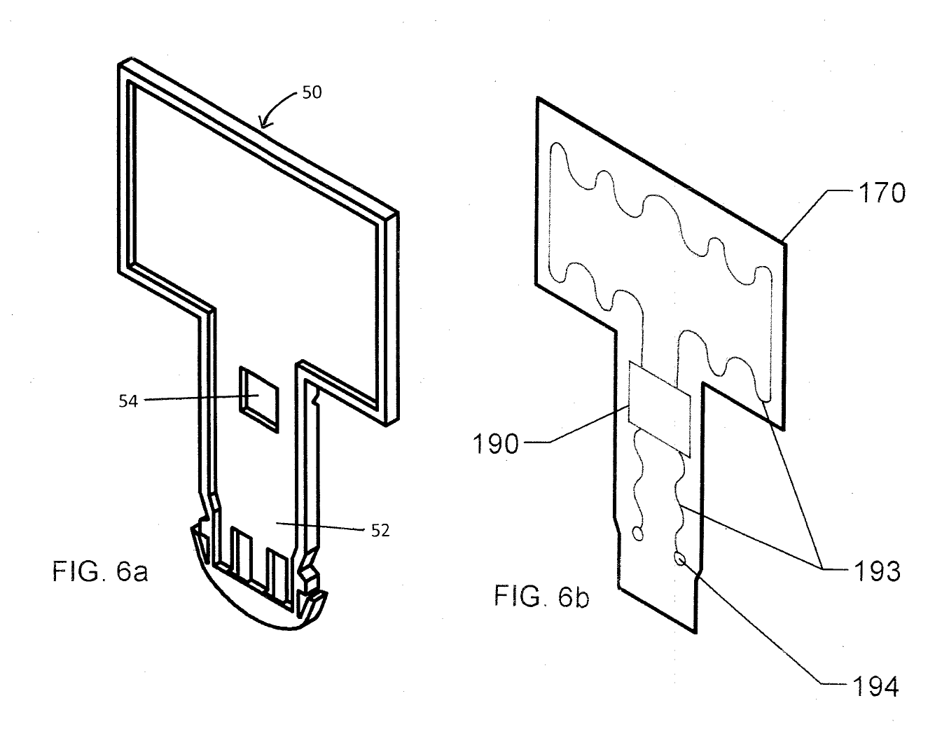

FIGS. 6a 6b show a frangible part having an RF chip and antenna according to another embodiment in which the transponder 190 and antenna 193 are embossed or otherwise set onto the internal surface of the cover 170. The antennae 193 include a pair of terminals 194 requiring separate connection to effect activation of the transponder 190.

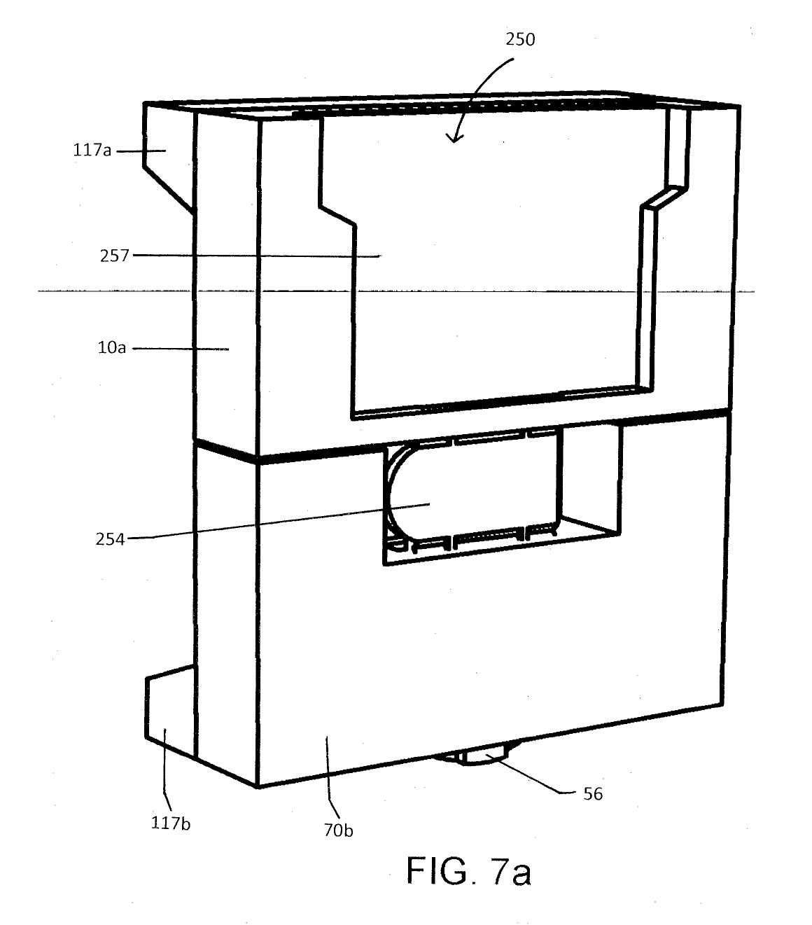

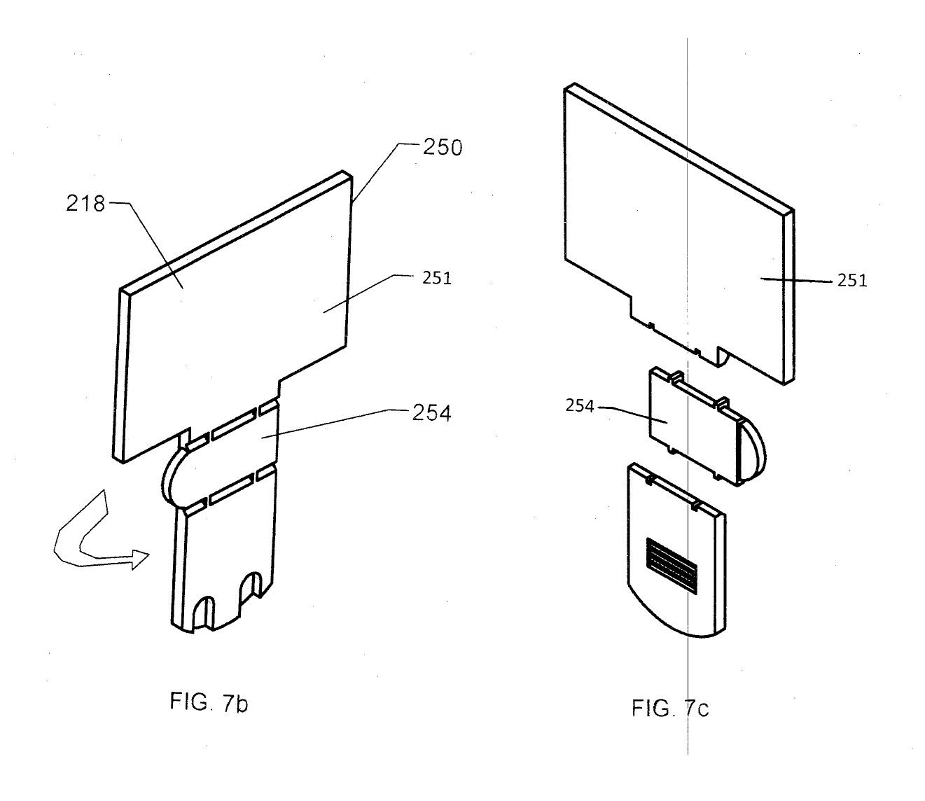

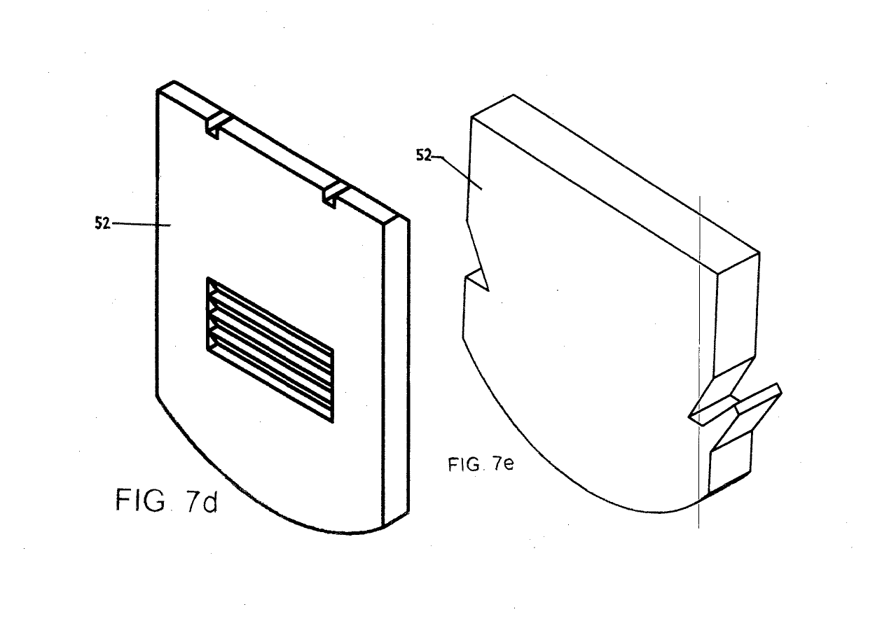

FIG. 7a shows a mid-tear seal and barcode arrangement according to another embodiment. FIGS. 7b-7e show the frangible part 250 having mid-portion 254 able to be torn away from the mid-section of the frangible part 250 to remove the transponder chip. The head 251 may include a barcode 218 as a primary or secondary level of identification and information.

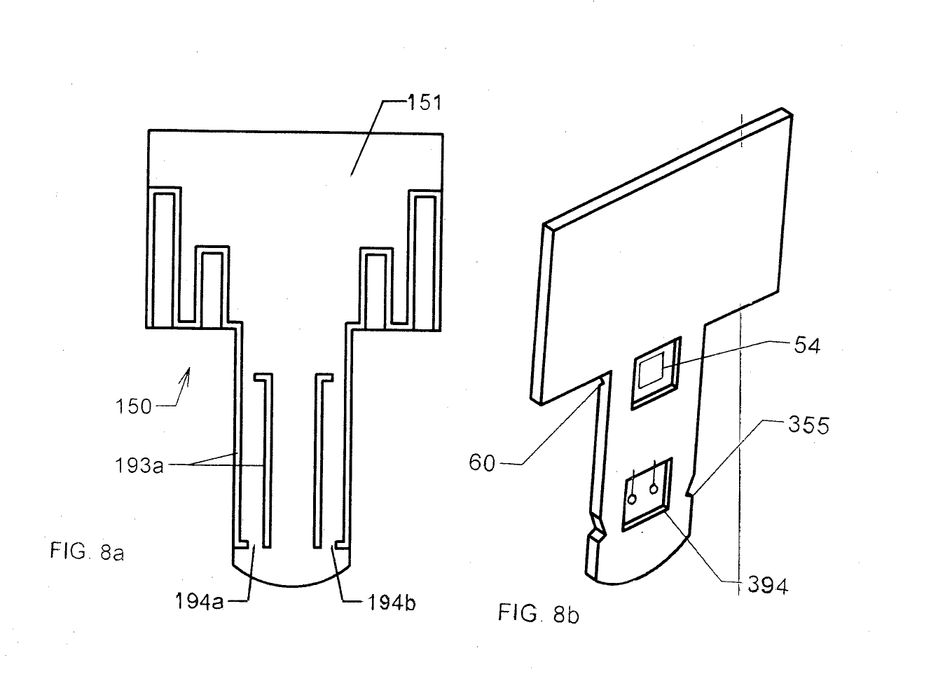

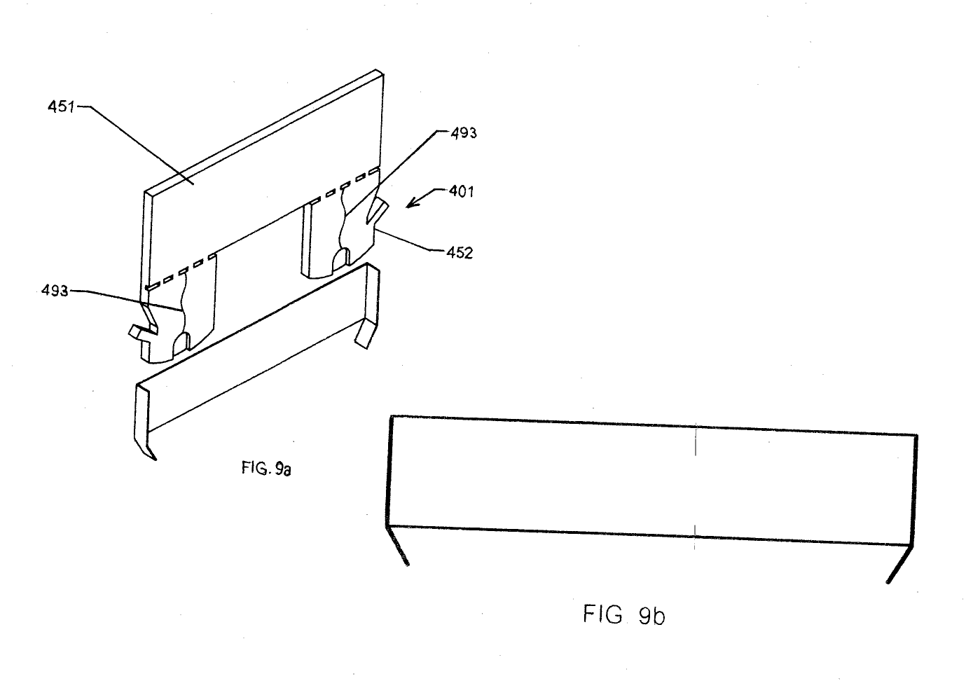

In FIG. 8a a frangible tag 150 is shown shaped in the form of a “T”, having a broad head portion 151 and a leg portion 152. Extending into and between the head and leg portions 151,152 is an antennae 193a with circuit interruption locations 194a,b. The antennae 193a is made from a good conductor, such as copper, and is configured for high sensitivity to radio frequency signals by careful spacing of parallel or adjacent lengths of the antennae 193a wire, positioning longest lengths of the antennae 193a at the periphery of the heard portion 151 and reducing the lengths of the antennae 193a towards the center of the nexus between the head portion 151 and the leg portion 152. This design and antennae layout lakes into consideration the effects on radio waves of the seal body (receptacle 10a-d) and the cover 70, so that it functions well in situ.

FIG. 8b shows a frangible part 350 with a mid-leg terminal 394 and side ramps 355 that complement barbs 332 in the second receptacle according to another embodiment.

FIGS. 9a-9b show a frangible part or components thereof according to a double leg seal embodiment 401 in which the seal 401 includes a pair of legs 452 bridged by a head 451. Each leg 452 comprises one or more terminals 494 which must be disconnected to disconnect the antennae 493. The legs 452 may be torn from the head 451 by sideways movement as shown in FIG. 9b.

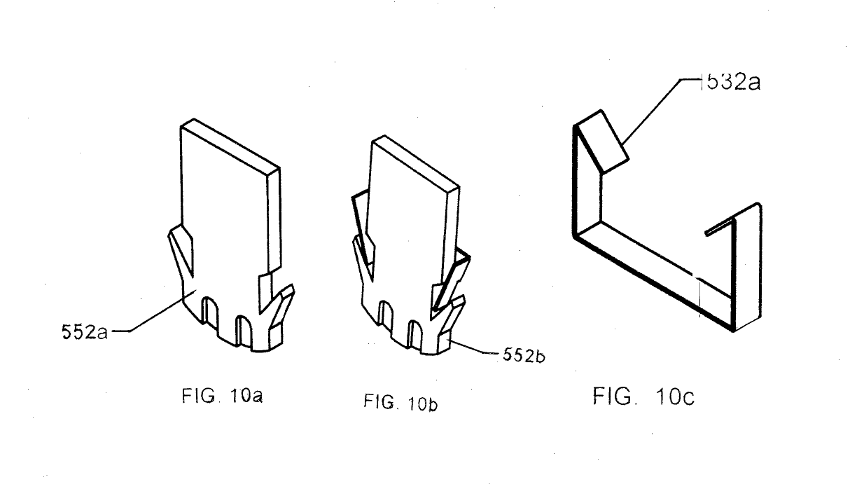

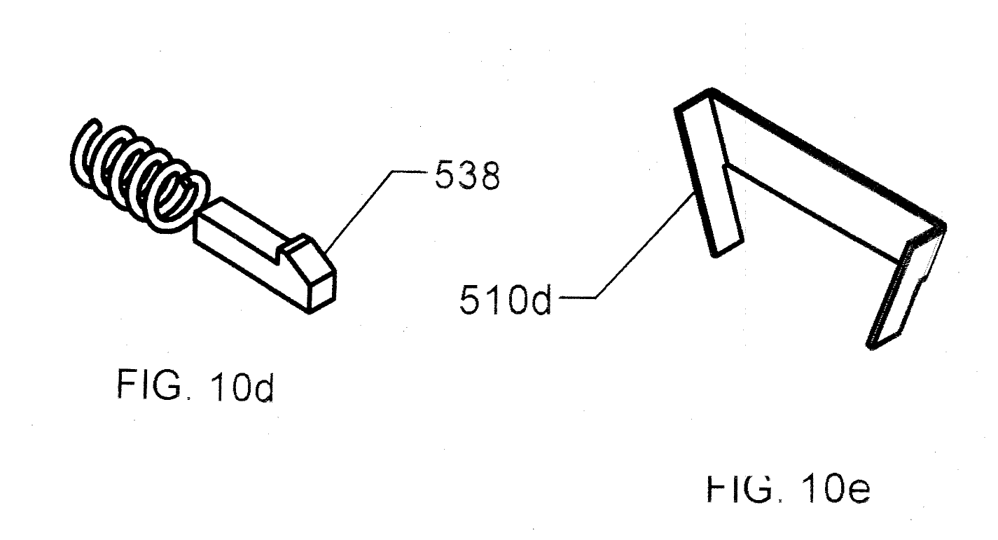

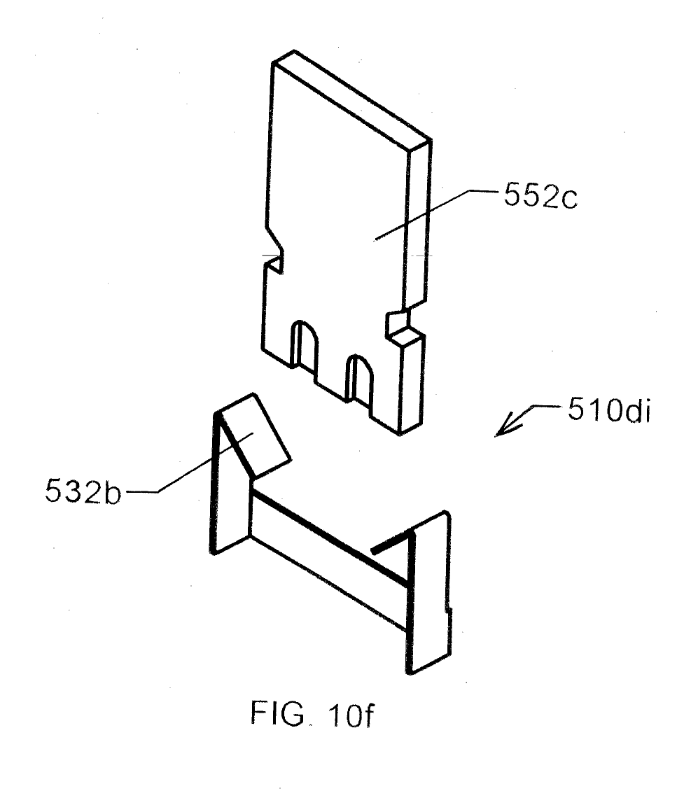

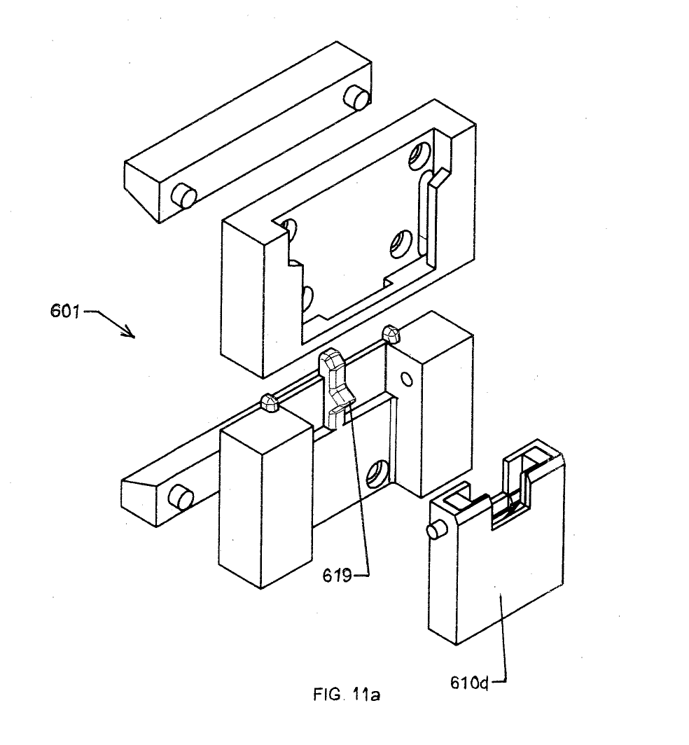

FIGS. 10a 10b show frangible parts 552a,b having side barbs adapted to cooperate with a second receptacle having complementary downward side barbs 532a shown FIG. 10c. FIG. 10d shows a second receptacle component 538 in the form of a sprung pivot pin. FIG. 10e shows a second receptacle 510d capable of pivoting about an axis normal to the plane of the frangible part 552a,b. FIG. 10f shows a frangible part leg 552c and second receptacle 510di with complementary downwardly extending barbs 532b.

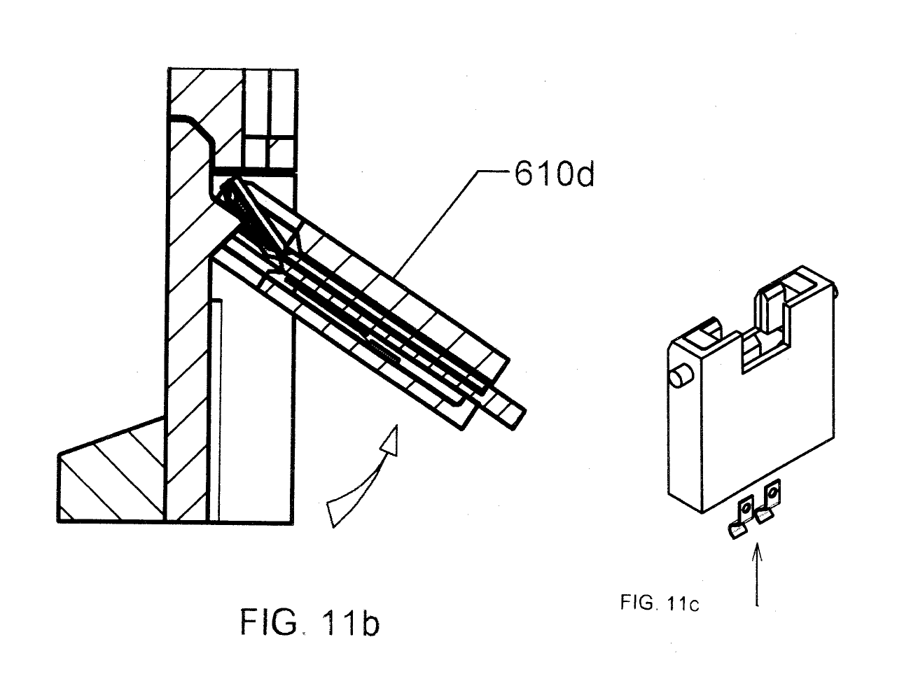

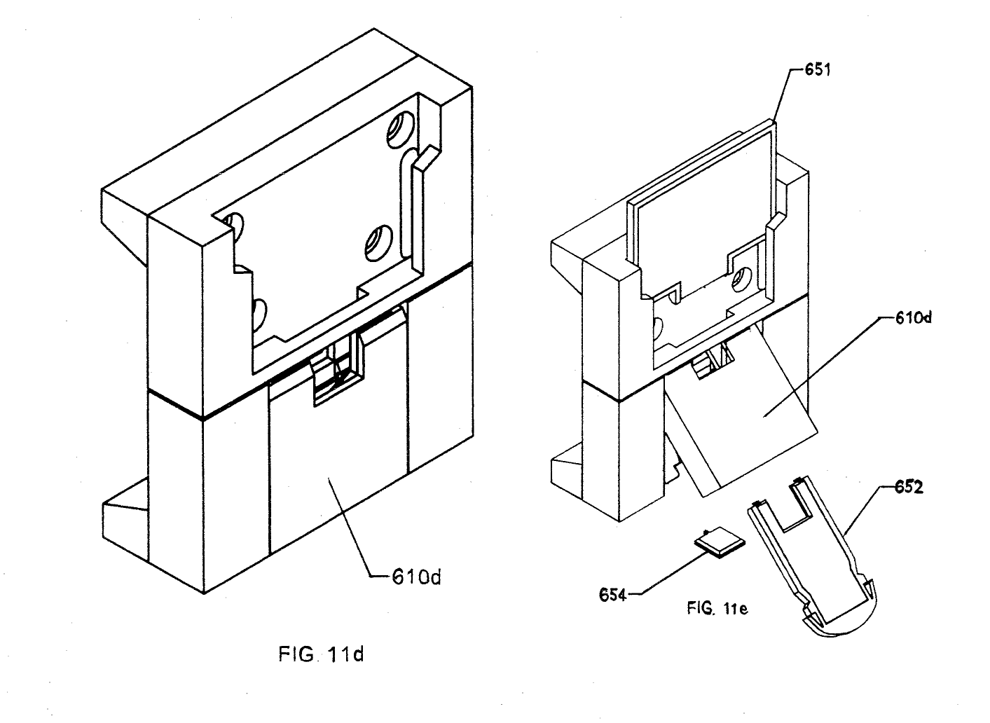

FIG. 11a-11c shows a seal 601 and chip destroyer 619 having barbed teeth to cut away at a weakened line. The seal 601 has a flip out chamber or second receptacle 610d. The embodiment shown in FIGS. 11d-11e is similar and shows the head 651 in the form of a removable flag and the leg portion 652 and chip or chip panel 654 able to be expelled once separated from the head portion 651.

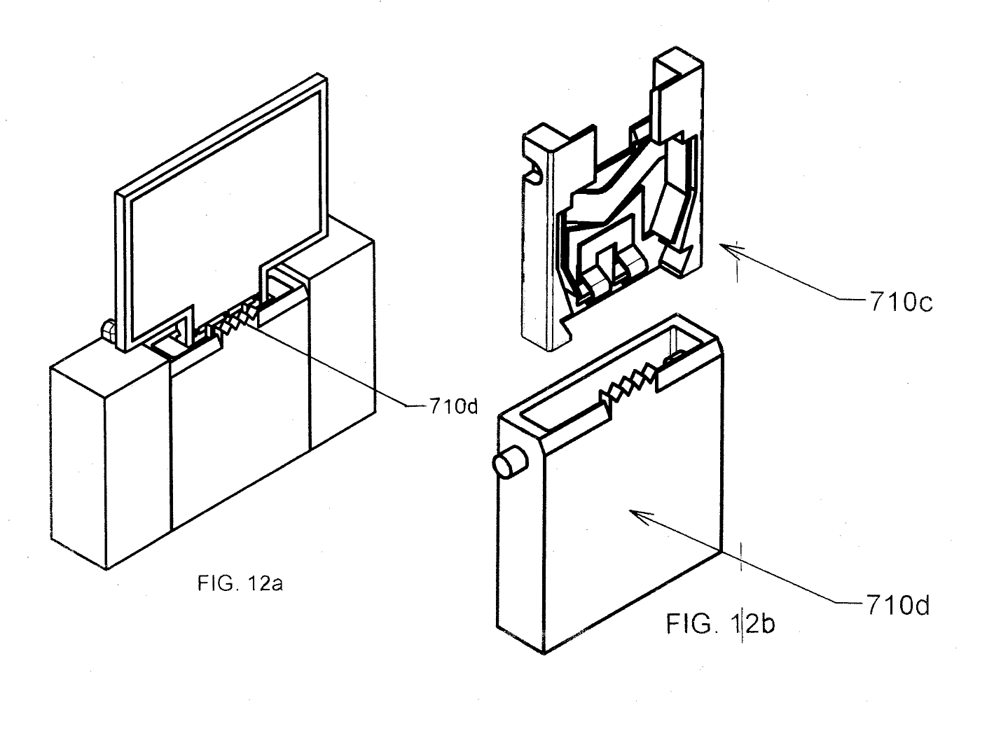

FIG. 12a shows a seal 701 having a tilt out chamber 710d according to another embodiment. FIG. 12b shows the seal 701 including detail of the configuration of the outer sleeve 710b and the inner sleeve 710c.

Throughout the specification and claims the word “comprise” and its derivatives are intended to have an inclusive rather than exclusive meaning unless the contrary is expressly stated or the context requires otherwise. That is, the word “comprise” and its derivatives will be taken to indicate the inclusion of not only the listed components, steps or features that it directly references, but also other components, steps or features not specifically listed, unless the contrary is expressly stated or the context requires otherwise.

Orientational terms used in the specification and claims such as vertical, horizontal, top, bottom, upper and lower are to be interpreted as relational and are based on the premise that the component, item, article, apparatus, device or instrument will usually be considered in a particular orientation, typically with the first receptacle uppermost.

It will be appreciated by those skilled in the art that many modifications and variations may be made to the methods of the invention described herein without departing from the spirit and scope of the invention.

1. A wirelessly detectable tamper-evident seal comprising:
a receptacle part; and
a frangible part,
said receptacle part comprising:
a first receptacle; and
a second receptacle,
said receptacle parts attachable to a container to seal a closure of the container and said frangible part comprising:
a first portion; and
a second portion,
said first and second portions frangibly connected to each other,
said first receptacle adapted to receive said first portion and said second receptacle adapted to receive said second portion by moving said frangible part in a first forward direction into engagement with said receptacle part,
said frangible part further comprising
a transponder,
said second portion able to be trapped against movement in the reverse direction to the first direction in said second receptacle to effect a tamper evident seal between said first and second receptacles, wherein said transponder comprise
at least two activity interruption locations, at least one of which must be connected to an antennae or antenna-like structure located on said receptacle to activate said transponder by inserting said frangible part in said receptacle part; and
wherein at both activity interruption locations the connection to said antennae or antenna-like structures must be broken by weakening or breaking the frangible connection between said first and second portions to effectively deactivate the transponder.

2. The wirelessly detectable tamper-evident seal according to claim 1, said first and second receptacles attachable respectively to either side of the closure, said transponder activatable by reception of said second portion in said second receptacle to seal the receptacle part together.

3. The wirelessly detectable tamper-evident seal according to claim 1, said first and second receptacles attachable respectively to either side of the closure, said transponder activatable by reception of said second portion in said second receptacle to seal the receptacle part together, and the breaking of said seal involves the separation of a wireless detectable portion of said transponder from said frangible part.

4. The wirelessly detectable tamper-evident seal according to claim 1, wherein the separation of said wireless detectable portion from said frangible part disconnects and makes said transponder inoperable.

5. The wirelessly detectable tamper-evident seal according to claim 1, wherein a used said receptacle part is reusable with a replacement frangible part.

6. The wirelessly detectable tamper-evident seal according to claim 1, wherein said transponder automatically transmits a radio signal upon reception of a designated incoming radio signal.

7. The wirelessly detectable tamper-evident seal according to claim 1, wherein said transponder is an RF transponder capable of being read by an RF transponder reader when the transponder is connected to the antenna which makes the transponder operable and able to be interrogated by said RF transponder reader.

8. The wirelessly detectable tamper-evident seal according to claim 7, wherein said transponder is passive, relying on electromagnetic radiation generated by said RF reader to power the RF chip through the collection of the RF reader signal via the antenna.

9. The wirelessly detectable tamper-evident seal according to claim 1, wherein said first portion is in the form of a head having at least one lateral extension that extends outside the line of said second portion.

10. The wirelessly detectable tamper-evident seal according to claim 9, wherein said first receptacle is a chamber adapted to receive said first portion comprising a head and said second receptacle is a chamber or frame adapted to receive said second portion comprising a leg.

11. The wirelessly detectable tamper-evident seal according to claim 1, wherein said receptacle part includes one or more detents adapted to engage one or more corresponding features on said second portion whereby to trap said second portion in said second receptacle.

12. The wirelessly detectable tamper-evident seal according to claim 1, wherein said receptacle part comprises at least two parts, including at least one movable part to receive the leg and a main body including a protruding part operable to disconnect and deactivate said transponder upon movement of said movable part.

13. The wirelessly detectable tamper-evident seal according to claim 12, wherein said first and second receptacles are attachable to the container to seal the closure of the container, the unauthorised separation of said receptacle part or a component thereof from the container being visibly evident.

14. The wirelessly detectable tamper-evident seal according to claim 3, wherein said first and second portions are frangibly connected to each other by weakened or score lines and said transponder chip constitutes a portion of said frangible part that is adapted to break away from the remainder of the frangible part structure, the frangible part further having one or more extensions, arms, legs or other components that are adapted to partially or fully separate from the remainder of said frangible part to deactivate the transponder on the breaking of the seal.

15. The wirelessly detectable tamper-evident seal according to claim 1, wherein said transponder comprises at least two circuit interruption locations that are connected to activate said transponder.

16. The wirelessly detectable tamper-evident seal according to claim 15, wherein said transponder is adapted to operate with one or both circuit interruption locations connected.

17. The wirelessly detectable tamper-evident seal according to claim 3, wherein said transponder chip is discretely displaceable from the frangible part to disconnect the transponder by virtually completely isolating said chip from any antennae or antenna-like structure that might otherwise be effective to continue energizing the chip despite the breaking of the seal.

18. A method for sealing a container with a wirelessly detectable tamper evident seal having a receptacle part comprising first and second receptacles and a frangible part comprising first and second portions frangibly connected to each other and comprising a transponder having a wireless detectable portion, the method comprising the steps of:
attaching said first receptacle and said second receptacle to the container;
receiving said first portion in said first receptacle and trapping said second portion in said second receptacle thereby activating said transponder and sealing said receptacle part together to tamper-evidently seal the container;
weakening or breaking the frangible connection between said first and second portions to break said seal; and
separating said wireless detectable portion from said frangible part to make said transponder inoperable,
said transponder including at least two activity interruption locations, at least one of which must be connected to antenna or antennae-like structures to activate said transponder and at both of which activity interruption locations the connection must be broken by weakening or breaking the frangible connection to effectively deactivate the transponder.

19. The method for sealing a container with a wirelessly detectable tamper evident seal accordingly claim 18, comprising the further steps of inserting said transponder comprising an antenna between said frangible part and a cover correspondingly shaped relative to said frangible part and in parallel plane relationship to said frangible part, and joining the frangible part and the cover together.

20. The method for sealing a container with a wirelessly detectable tamper evident seal according to claim 18, comprising the steps of sealing multiple containers sequentially by:
reusing said receptacle part for each new container to be sealed and employing multiple frangible parts for a single use for each new container to be sealed; and
breaking the seal by causing the weakening or the breaking of the frangible connection between the first and second portions and separating said wireless detectable portion from said frangible part to irretrievably destroy said frangible part without damaging said receptacle part making it reusable with a replacement said frangible part.
